(19) United States
(12) Patent Application Publication
(10) Pub. No.: US 2026/0302760 A1
(43) Pub. Date: Oct. 1, 2026

(54) MOBILE VEHICLE CONTROL SYSTEM AND METHOD

(71) Applicant: KOREA ATOMIC ENERGY RESEARCH INSTITUTE, Daejeon (KR)

(72) Inventors: Minwoong LEE, Daejeon (KR); Nam-Ho LEE, Daejeon (KR); Donghan KI, Daejeon (KR); Young Gwan HWANG, Daejeon (KR); Hui-Jeong GWON, Daejeon (KR)

(73) Assignee: KOREA ATOMIC ENERGY RESEARCH INSTITUTE, Daejeon (KR)

(21) Appl. No.: 19/629,755

(22) Filed: Mar. 26, 2026

(30) Foreign Application Priority Data
Mar. 28, 2025 (KR) 10-2025-0039982

(51) Int. Cl. H02H 5/00; G21J 5/00; H02H 1/00; H02H 3/06

(52) U.S. Cl. CPC H02H 5/005; G21J 5/00; H02H 1/0007; H02H 3/06

(57) ABSTRACT

Provided are a mobile vehicle control system and method capable of reducing equipment damage and loss caused by radiation and EMP by stopping the operation of a power supply device upon receiving a detection signal for at least one of radiation and electromagnetic pulse and restarting the power supply device after a predetermined period of time.

### CROSS-REFERENCE TO RELATED APPLICATIONS

This application claims priority under 35 U.S.C. § 119 to Korean Patent Application No. 10-2025-0039982, filed on Mar. 28, 2025, in the Korean Intellectual Property Office, the disclosure of which is incorporated herein by reference in its entirety.

### TECHNICAL FIELD

The following disclosure relates to a mobile vehicle control system and method, and in particular, to a mobile vehicle control system and method capable of operating in extreme environments, such as nuclear explosions or electromagnetic pulse (EMP) attacks.

### BACKGROUND

The prompt gamma rays generated by high-altitude nuclear explosions, electromagnetic pulses (HEMPs), and electromagnetic waves emitted by EMP bomb attacks may cause significant damage to electronic equipment of military weapon systems during missions, paralyzing warfare systems and resulting in a loss of military capabilities.

In particular, when drones, which are mobile vehicles utilized for surveillance and reconnaissance, communication, detection, transport support, and strike missions during wartime, are exposed to nuclear radiation and HEMP during a mission, errors may occur in communication, control, and power functions due to malfunctions in internal electronic components to cause abnormal crashes, impacts, or damage to drones, which may potentially lead to mission failure, information leakage, or permanent destruction, and therefore, there is a critical need for technological development to ensure nuclear and EMP protection for drones and to guarantee mission success.

Currently, passive protection methods, such as electromagnetic shielding and blocking EMP penetration through protection circuits have been widely used as countermeasures against nuclear radiation and HEMP. However, due to the nature of mobile vehicles operated in the air, there is a problem in that the application of such countermeasures is limited when considering weight, volume, and equipment requirements.

### RELATED ART DOCUMENT

### Patent Document

Korean Patent No. 10-1811295 (Registration Date: December 15, 2017)

### SUMMARY

An exemplary embodiment of the present invention is directed to providing a mobile vehicle control system and method capable of reducing equipment damage and loss caused by radiation and EMP by stopping the operation of a power supply device upon receiving a detection signal for at least one of radiation and electromagnetic pulse and restarting the power supply device after a predetermined period of time.

In one general aspect, a mobile vehicle control system includes: a sensor unit including at least one of a radiation sensor detecting radiation and an electromagnetic pulse (EMP) sensor detecting an electromagnetic pulse and providing a detection signal for at least one of the radiation and the electromagnetic pulse; a power supply device supplying power; and a controller controlling the power supply device based on a detection signal received from the sensor unit, wherein the controller, upon receiving at least one of a radiation detection signal and an EMP detection signal from the sensor unit, stops an operation of the power supply device and restarts the power supply device after a predetermined period of time.

The radiation sensor may be a silicon-based semiconductor structure.

The EMP sensor may be an electric field antenna detecting an early-stage high-intensity electric field E1 of a high-altitude electromagnetic pulse (HEMP).

The radiation sensor may generate a radiation detection signal upon detecting radiation exceeding a preset reference radiation.

The EMP sensor may generate an EMP detection signal upon detecting an electric field exceeding a preset reference electric field.

The controller may readjust an attitude of a mobile vehicle based on a preset control parameter after the power supply device is restarted.

In another general aspect, a mobile vehicle control method of a mobile vehicle control system includes: a danger detection operation in which a sensor unit provides a detection signal for at least one of a radiation sensor detecting radiation and an EMP sensor detecting an electromagnetic pulse; a power cut-off operation in which a controller stops an operation of a power supply device upon receiving at least one of a radiation detection signal and an EMP detection signal from the sensor unit; and a power re-supply operation in which the controller restarts the power supply device after a predetermined period of time.

The radiation sensor may generate a radiation detection signal upon detecting radiation exceeding a preset reference radiation.

The EMP sensor may generate an EMP detection signal upon detecting an electric field exceeding a preset reference electric field.

The mobile vehicle control method may further include: an attitude readjustment operation in which, after the power re-supply operation, the controller readjusts an attitude of a mobile vehicle based on a preset control parameter after the power supply device is restarted.

Other features and aspects will be apparent from the following detailed description, the drawings, and the claims.

### BRIEF DESCRIPTION OF THE DRAWINGS

FIG. 1 is a schematic diagram illustrating a mobile vehicle control system according to an exemplary embodiment of the present invention.

FIG. 2 is a flowchart illustrating a mobile vehicle control method according to an exemplary embodiment of the present invention.

### DETAILED DESCRIPTION OF EXEMPLARY EMBODIMENTS

The aspects, features, and advantages of the disclosure will become apparent from the following description of the exemplary embodiments with reference to the accompanying drawings, which are set forth hereinafter. The specific structures and functional description will be only provided for the purpose of illustration of the exemplary embodiments according to the concept of the invention, so that the exemplary embodiments of the invention may be embodied in many different forms and should not be construed as being limited to the exemplary embodiments set forth herein. The exemplary embodiments according to the concept of the invention may be changed to diverse forms, so that the invention will be described and illustrated with reference to specific exemplary embodiments. However, it should be understood that the exemplary embodiments according to the concept of the invention are not intended to limit the invention to the specific exemplary embodiments disclosed, but they include all the modifications, equivalences, and substitutions, which are included in the scope and spirit of the invention. It will be understood that although the terms “first,” “second,” etc. may be used herein to describe various devices, these devices should not be limited by these terms. These terms are only used to distinguish one device from another device. Thus, a first device discussed below could be termed a second device and vice versa without departing from the nature of the disclosure. It will be understood that when a device is referred to as being “connected or coupled” to another device, it may be directly connected or coupled to the other device or intervening devices may be present therebetween. In contrast, when a device is referred to as being “directly connected” or “directly coupled” to another device, there are no intervening devices present. Other expressions, such as “between,” “directly between,” “adjacent,” or “directly adjacent” should be understood in a similar manner. The terminology used herein is for the purpose of describing particular exemplary embodiments only and is not intended to limit the invention. As used herein, the singular forms “a,” “an” and “the” are intended to include the plural forms as well, unless the context clearly indicates otherwise. It will be further understood that the terms “comprises” and/or “comprising,” or “includes” and/or “including,” when used in this specification, specify the presence of stated features, integers, steps, operations, devices and/or components, but do not preclude the presence or addition of one or more other features, integers, steps, operations, devices, components and/or groups thereof. Unless otherwise defined, the meaning of all terms including technical and scientific terms used herein are the same as those commonly understood by one of ordinary skill in the art to which the disclosure pertains. It will be further understood that terms, such as those defined in commonly used dictionaries, should be interpreted as having a meaning which is consistent with their meaning in the context of the relevant art and the disclosure, and will not be interpreted in an idealized or overly formal sense unless expressly so defined herein. Hereinafter, exemplary embodiments will be described in detail with reference to the accompanying drawings. The same reference numerals indicated in the drawings refer to similar devices throughout. In addition, a system refers to a set of components including devices, mechanisms, and means that are organized and interact regularly to perform a necessary function.

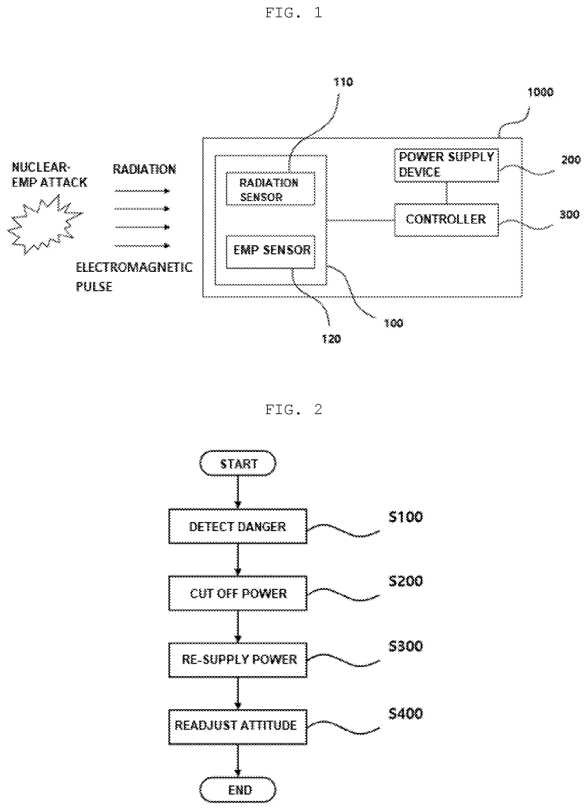

FIG. 1 is a schematic diagram illustrating a mobile vehicle control system according to an exemplary embodiment of the present invention. The mobile vehicle control system according to an exemplary embodiment of the present invention will now be described in detail with reference to FIG. 1.

As illustrated in FIG. 1, a mobile vehicle control system 1000 according to an exemplary embodiment of the present invention may include a sensor unit 100, a power supply device 200, and a controller 300. Each component may be included in one or more computing processors, including a computer or the like, to perform operations.

Each component is described in detail below. The sensor unit 100 may include at least one of a radiation sensor 110 detecting radiation and an electromagnetic pulse (EMP) sensor 120 detecting an EMP.

The radiation sensor 110 may detect pulse-type prompt gamma rays generated at an initial stage of a nuclear explosion.

In addition, the radiation sensor 110 may have a silicon-based semiconductor structure.

Accordingly, the radiation sensor 110 may be manufactured in a subminiature size to be easily mounted on a mobile vehicle. Furthermore, since sensitivity may be controlled by modifying silicon process parameters, the sensitivity may be enhanced to enable detection starting from a low radiation level.

However, this is merely an example and the present invention is not limited thereto; any structure that is subminiature and allows for sensitivity control may be used.

In addition, the EMP sensor 120 may be an electric field antenna that detects an early-stage high-intensity electric field E1 of a high-altitude electromagnetic pulse (HEMP).

However, this is merely an example and the present invention is not limited thereto; any EMP sensor capable of detecting high-power microwave (HPM) and ultra-wideband (UWB) electric fields generated by EMP bombs or EMP guns may be used.

In addition, the sensor unit 100 may provide a detection signal for at least one of the radiation detected by the radiation sensor 110 and the electromagnetic pulse detected by the EMP sensor 120.

Specifically, the sensor unit 100 may provide at least one detection signal among a radiation detection signal generated by radiation detection by the radiation sensor 110 and an EMP detection signal generated by electromagnetic pulse detection by the EMP sensor 120.

The conditions for generating detection signals for the radiation sensor 110 and the EMP sensor 120 are described in detail below.

First, the radiation sensor 110 may generate a radiation detection signal when it detects radiation exceeding a preset reference radiation level.

The reference radiation level may be a value arbitrarily set by a user or a value previously set during the manufacture of the radiation sensor.

For example, since the pulse-type prompt gamma rays generated in the early stages of a high-altitude nuclear explosion are generally 10 to 100 mSv/s, the reference radiation may be 10 mSv/s.

Next, the EMP sensor 120 may generate an EMP detection signal upon detecting an electric field that exceeds a preset reference electric field.

For example, since the maximum field strength of the early stage high-intensity electric field E1 of a high-altitude electromagnetic pulse (HEMP) is 50 kV/m, the reference electric field may be 51 kV/m, which is approximately 1 kV/m higher.

This allows the system to operate only in dangerous situations, such as nuclear explosions, and to detect abnormal radiation or electromagnetic pulses.

The power supply device 200 may supply power to components within the mobile vehicle operated by power.

At this time, the power supply device 200 may be operated or stopped by the controller 300.

The controller 300 may control the power supply device 200 based on a detection signal received from the sensor unit 100.

Specifically, the controller 300 may stop the operation of the power supply device 200 upon receiving at least one of a radiation detection signal and an EMP detection signal from the sensor unit 100.

In other words, the controller 300 stops the operation of the power supply device 200 when a radiation detection signal is generated by the radiation sensor 110 among the radiation sensor 110 and EMP sensor 120 and the radiation detection signal is received from the sensor unit 100, when an EMP detection signal is generated by the EMP sensor 120 among the radiation sensor 110 and EMP sensor 120 and the EMP detection signal is received from the sensor unit 100, or when a radiation detection signal and an EMP detection signal are generated respectively by the radiation sensor 110 and the EMP sensor 120, and the radiation detection signal and the EMP detection signal are received from the sensor unit 100.

In addition, when the power supply device 200 is stopped, the controller 300 may restart the power supply device 200 after a predetermined period of time.

Here, the time required for the power supply device 200 to be restarted may be arbitrarily set by the user.

Accordingly, it is possible to reduce damage to semiconductor devices, circuits, and sensors inside the mobile vehicle caused by radiation or EMP from a nuclear explosion, to prevent data loss and errors in internal storage devices or memories, and further to reduce maintenance costs for the mobile vehicle.

After the power supply device 200 is restarted after the predetermined period of time, the attitude of the mobile vehicle in free fall has to be immediately readjusted to enable normal flight.

However, in the related art mobile vehicle control system, it takes 30 or more seconds to readjust the attitude and resume normal flight after restarting. This may lead to physical damage due to collisions, crashes, or rotations of the mobile vehicle, and in addition, given the nature of mobile vehicles performing specific missions, such as surveillance, reconnaissance, strikes, and transport, vulnerability to enemy attacks may increase and the likelihood of failure in performing certain missions may increase.

Therefore, an immediate attitude readjustment process is required after the power supply device is restarted.

To this end, the controller 300 may readjust the attitude of the mobile vehicle based on preset control parameters after the power supply device 200 is restarted.

Here, the control parameters are parameters arbitrarily set by the user. The control parameters may include target angles (roll, pitch, and yaw), PID control parameters (proportional-integral-differential coefficients), and motor output ratios for controlling the attitude of the mobile vehicle. However, the control parameters are not limited to these parameters and may be any parameter for controlling the attitude of the mobile vehicle.

Accordingly, immediate attitude readjustment of the mobile vehicle may be performed within one second, physical damage caused by collisions, crashes, or rotations may be prevented, and a smooth return to the original mission may be facilitated.

FIG. 2 is a flowchart illustrating a mobile vehicle control method according to an exemplary embodiment of the present invention. The mobile vehicle control method according to an exemplary embodiment of the present invention will now be described in detail with reference to FIG. 2.

As illustrated in FIG. 2, the mobile vehicle control method according to an exemplary embodiment of the present invention may include a danger detection operation (S100), a power cut-off operation (S200), and a power resupply operation (S300). Each operation is performed by the components included in the mobile vehicle control system 1000.

To describe each operation in detail, in the danger detection operation (S100), the sensor unit 100 may provide a detection signal for at least one of the radiation sensor 110 that detects radiation and the EMP sensor 120 that detects electromagnetic pulses.

Specifically, in the danger detection operation (S100), the sensor unit 100 may provide at least one detection signal among a radiation detection signal generated by the radiation sensor 110 upon detection of radiation and an EMP detection signal generated by the EMP sensor 120 upon detection of electromagnetic pulses.

Here, the conditions for generating detection signals for the radiation sensor 110 and EMP sensor 120 will be described in detail. First, the radiation sensor 110 may generate a radiation detection signal upon detecting radiation exceeding a preset reference radiation.

The reference radiation may be a value arbitrarily set by the user or a value previously set during the manufacturing of the radiation sensor.

For example, since the radiation dose at which electronic components are damaged by pulse-type prompt gamma rays generated in the early stages of a high-altitude nuclear explosion is generally 2×10⁶~2×10⁷Gy, the reference radiation may be 2×10⁴~2×10⁵ Gy, which is about 1/100 to 1/1000 lower than the damage level. This reference dose may be adjusted by the controller.

Next, the EMP sensor 120 may generate an EMP detection signal upon detecting an electric field exceeding a preset reference electric field.

For example, since the maximum electric field strength of the early stage high-intensity electric field E1 of a high-altitude electromagnetic pulse (HEMP) is 50 kV/m, the reference electric field may be 5 to 10 kV/m, which is ⅕ to 1/10 lower than the maximum strength but higher than the electric field of 1 to 2 kV/m of a general environment that may be generated by communication or radar systems. The reference electric field may be adjusted by the controller

Through this, the system may operate only in dangerous situations, such as nuclear explosions, and may detect abnormal radiation or electromagnetic pulses.

In the power cut-off operation (S200), the controller 300 may stop the operation of the power supply device 200 upon receiving at least one of the radiation detection signal and the EMP detection signal from the sensor unit 100.

In other words, when a radiation detection signal is generated by the radiation sensor 110 among the radiation sensor 110 and EMP sensor 120 and the radiation detection signal is received from the sensor unit 100, or when an EMP detection signal is generated by the EMP sensor 120 among the radiation sensor 110 and EMP sensor 120 and the EMP detection signal is received from the sensor unit 100, or when a radiation detection signal and an EMP detection signal are generated respectively by the radiation sensor 110 and the EMP sensor 120, and the radiation detection signal and the EMP detection signal are received from the sensor unit 100, the operation of the power supply device 200 is stopped.

In the power resupply operation (S300), the controller 300 may restart the power supply device 200 after a predetermined period of time, when the power supply device 200 is stopped.

At this time, the time required for the power supply device 200 to be restarted may be a value arbitrarily set by the user.

Accordingly, it is possible to reduce damage to semiconductor devices, circuits, and sensors inside the mobile vehicle caused by radiation or EMP from a nuclear explosion, prevent data loss and errors in internal storage devices or memories, and further reduce maintenance costs for the mobile vehicle.

After the power supply unit 200 is restarted following the predetermined period of time, the attitude of the mobile vehicle in free fall has to be immediately readjusted to enable normal flight. However, to address the problem of requiring 30 seconds or more to readjust the attitude of the mobile vehicle and enable normal flight, the mobile vehicle control method according to an exemplary embodiment of the present invention may further include an attitude readjustment operation (S400).

In the attitude readjustment operation (S400), the controller 300 may readjust the attitude of the mobile vehicle based on the preset control parameter, after the power resupply operation (S300).

Here, the control parameters, as parameters arbitrarily set by the user, may be target angles (roll, pitch, yaw) for controlling the attitude, PID control parameters (proportional-integral-derivative coefficients), and motor output ratios; however, the present invention is not limited thereto, and any parameter for controlling the attitude of the mobile vehicle may be used.

Accordingly, immediate attitude readjustment may be performed within one second, physical damage due to collisions, crashes, or rotations may be prevented, and a smooth return to the original mission may be facilitated.

In summary, the mobile vehicle control system and method according to an exemplary embodiment of the present invention have the advantage of reducing equipment damage and loss caused by radiation and EMP by stopping the operation of the power supply device upon receiving a detection signal for at least one of radiation and an electromagnetic pulse and restarting the power supply device after a predetermined period of time.

The present invention has the advantage of reducing equipment damage and loss caused by radiation and EMP and reducing costs.

In addition, since drones may be used as substitutes for human personnel in radioactive environments, worker radiation exposure may be minimized and safety may be improved.

Although the preferred exemplary embodiments of the present invention have been described above, the exemplary embodiments disclosed in the present invention are not intended to limit the technical spirit of the present invention, but are only for explanation. Therefore, the technical spirit of the present invention includes not only each disclosed exemplary embodiment, but also a combination of the disclosed exemplary embodiments, and in addition, the scope of the technical spirit of the present invention is not limited by these exemplary embodiments. In addition, those skilled in the art to which the present invention pertains may make many changes and modifications to the present invention without departing from the spirit and scope of the appended claims, and all such appropriate changes and modifications, as equivalents, are to be regarded as falling within the scope of the present invention.

### DETAILED DESCRIPTION OF MAIN ELEMENTS

100: Sensor Unit
110: Radiation Sensor
120: EMP Sensor
200: Power supply device
300: Controller
1000: Mobile vehicle control system

What is claimed is:

1. A mobile vehicle control system comprising:
a sensor unit including at least one of a radiation sensor detecting radiation and an electromagnetic pulse (EMP) sensor detecting an electromagnetic pulse and providing a detection signal for at least one of the radiation and the electromagnetic pulse;
a power supply device supplying power; and
a controller controlling the power supply device based on a detection signal received from the sensor unit, wherein
the controller, upon receiving at least one of a radiation detection signal and an EMP detection signal from the sensor unit, stops an operation of the power supply device and restarts the power supply device after a predetermined period of time.

2. The mobile vehicle control system of claim 1, wherein the radiation sensor is a silicon-based semiconductor structure.

3. The mobile vehicle control system of claim 1, wherein the EMP sensor is an electric field antenna detecting an early-stage high-intensity electric field E1 of a high-altitude electromagnetic pulse (HEMP).

4. The mobile vehicle control system of claim 1, wherein the radiation sensor generates a radiation detection signal upon detecting radiation exceeding a preset reference radiation.

5. The mobile vehicle control system of claim 1, wherein the EMP sensor generates an EMP detection signal upon detecting an electric field exceeding a preset reference electric field.

6. The mobile vehicle control system of claim 1, wherein the controller readjusts an attitude of a mobile vehicle based on a preset control parameter after the power supply device is restarted.

7. A mobile vehicle control method of a mobile vehicle control system, the mobile vehicle control method comprising:
a danger detection operation in which a sensor unit provides a detection signal for at least one of a radiation sensor detecting radiation and an EMP sensor detecting an electromagnetic pulse;
a power cut-off operation in which a controller stops an operation of a power supply device upon receiving at least one of a radiation detection signal and an EMP detection signal from the sensor unit; and
a power re-supply operation in which the controller restarts the power supply device after a predetermined period of time.

8. The mobile vehicle control method of claim 7, wherein the radiation sensor generates a radiation detection signal upon detecting radiation exceeding a preset reference radiation.

9. The mobile vehicle control method of claim 7, wherein the EMP sensor generates an EMP detection signal upon detecting an electric field exceeding a preset reference electric field.

10. The mobile vehicle control method of claim 7, further comprising an attitude readjustment operation in which, after the power re-supply operation, the controller readjusts an attitude of a mobile vehicle based on a preset control parameter after the power supply device is restarted.
